(19) United States
(12) Patent Application Publication
(10) Pub. No.: US 2022/0371151 A1
(43) Pub. Date: Nov. 24, 2022

(54) POLISHING APPARATUS, INFORMATION PROCESSING SYSTEM, INFORMATION PROCESSING METHOD, AND PROGRAM

(71) Applicant: EBARA CORPORATION, Tokyo (JP)

(72) Inventor: Akira NAKAMURA, Tokyo (JP)

(21) Appl. No.: 17/765,388

(22) PCT Filed: Sep. 16, 2020
(86) PCT No.: PCT/JP2020/035106

§ 371 Date: Mar. 30, 2022

(30) Foreign Application Priority Data
Oct. 4, 2019 (JP) 2019-183750

(51) Int. Cl. B24B 37/005; B24B 37/20

(52) U.S. Cl. CPC B24B 37/005; B24B 37/20

(57) ABSTRACT

Included are a polishing table provided with an eddy current sensor, the polishing table configured to rotate; a polishing head configured to face the polishing table, the polishing head configured to rotate, the polishing head having a surface which faces the polishing table and to which a substrate is configured to be attached; and a processor configured to generate preprocessed data on a target substrate by executing predetermined preprocessing on an output signal when the eddy current sensor is at each position facing a target substrate during polishing processing of a target substrate to determine a metal line height at at least one position of the target substrate by inputting preprocessed data on the target substrate to a learned machine learning model using a learning data set in which data after predetermined preprocessing is executed on an output signal when the eddy current sensor is at each position facing a substrate is set as an input and a metal line height at at least one position of the substrate is set as an output.

### TECHNICAL FIELD

The present invention relates to a polishing apparatus, an information processing system, an information processing method, and a program.

### BACKGROUND ART

Chemical mechanical polishing (hereinafter referred to as CMP) is a technique of increasing a mechanical polishing (surface removal) effect due to a relative movement between a polishing agent and an object to be polished by a surface chemical action of the polishing agent (abrasive grain) itself or an action of a chemical component contained in a polishing liquid to obtain a high-speed and smooth polished surface.

The polishing apparatus performs mounting a controller for detecting a polishing end point and detecting an optimum polishing end point using, for example, an eddy current sensor (see Patent Literature 1). The eddy current sensor is installed, for example, under the polishing table and generates lines of magnetic force in a direction penetrating the polishing table. When the polishing table rotates, the eddy current sensor rotates together with the polishing table and passes under the wafer held by the top ring. At this time, when a conductive film is present on the wafer surface, an eddy current occurs on the wafer surface. When the eddy current flows, lines of magnetic force are generated in a direction opposite to that of the original lines of magnetic force. Measuring the intensity of lines of magnetic force generated in the opposite direction measures the thickness of the conductive film.

### CITATION LIST

### Patent Literature

Patent Literature 1: JP 2005-121616 A

### SUMMARY OF INVENTION

### Technical Problem

There is a demand for controlling the height of wiring during CMP processing, using microfabrication of semiconductors. When a polishing apparatus using CMP measures a wafer having a wiring pattern with an eddy current sensor during CMP processing of the wafer, a signal having irregularities can be observed. There is a correlation between the irregularities and the size of the wiring pattern (pattern shape, width, and height).

However, during the CMP processing, since each of the wafer, and the eddy current sensor fixed under the polishing table moves circularly, and the wiring pattern changes variously depending on the product, the irregularity pattern that appears also varies, and the metal line height (the thickness of the conductive film) cannot be simply calculated.

The present invention has been made in view of the above problems, and has an object to provide a polishing apparatus, an information processing system, an information processing method, and a program capable of estimating a metal line height of a substrate during polishing.

### Solution to Problem

A polishing apparatus according to a first aspect of the present invention includes: a polishing table provided with an eddy current sensor, the polishing table configured to rotate; a polishing head configured to face the polishing table, the polishing head configured to rotate, the polishing head having a surface which faces the polishing table and to which a substrate is configured to be attached; and a processor configured to generate preprocessed data on a target substrate by executing predetermined preprocessing on an output signal when the eddy current sensor is at each position facing a target substrate during polishing processing of a target substrate to determine a metal line height at at least one position of the target substrate by inputting preprocessed data on the target substrate to a learned machine learning model using a learning data set in which data after predetermined preprocessing is executed on an output signal when the eddy current sensor is at each position facing a substrate is set as an input and a metal line height at at least one position of the substrate is set as an output.

With this configuration, the metal line height at at least one position of the target substrate by inputting the preprocessed data on the target substrate to the learned machine learning model using the learning data set in which the data after the predetermined preprocessing is executed on the output signal when the eddy current sensor is at each position facing the substrate is set as an input and the metal line height at the at least one position of the substrate is set as an output can be estimated.

A polishing apparatus according to a second aspect of the present invention is the polishing apparatus according to the first aspect, in which when the determined metal line height reaches a predetermined metal line height, the processor performs control to finish polishing of the target substrate.

With this configuration, the polishing can be automatically terminated when the predetermined metal line height has been reached.

A polishing apparatus according to a third aspect of the present invention is the polishing apparatus according to the first or second aspect, in which the polishing head is provided with an airbag for pressing a substrate, and the processor controls a pressure distribution in the airbag according to distribution of the determined metal line height.

With this configuration, the uniformity of the height (for example, the metal line height) of the polished surface of the substrate can be improved.

A polishing apparatus according to a fourth aspect of the present invention is the polishing apparatus according to any one of the first to third aspects, in which an input of the machine learning model further includes a thickness of a polishing pad, a rotation speed of a polishing table, and/or a rotation speed of a polishing head.

With this configuration, since the amount of one scraping can be changed depending on the thickness of the polishing pad, the rotation speed of the polishing table, and/or the rotation speed of the polishing head, considering one or more of these parameters allows the estimation accuracy of the metal line height to be improved.

A polishing apparatus according to a fifth aspect of the present invention is the polishing apparatus according to any one of the first to fourth aspects, the polishing apparatus including a plurality of the eddy current sensors, and an input of the machine learning model is data after the preprocessing is executed on an output signal at each position facing the target substrate in identical polishing-table rotation-circling of the plurality of the eddy current sensors.

With this configuration, the data after the preprocessing is executed on the output signals in the same polishing-table rotation-circling of the plurality of eddy current sensors is used as the input of the machine learning model, so that even if noise is placed on one output signal, if no noise is placed on the other output signals, the metal line height can be estimated by using a plurality of output signals in the same circling. Thus, robustness of estimation of the metal line height can be improved.

A polishing apparatus according to a sixth aspect of the present invention is the polishing apparatus according to any one of the first to fourth aspects, the polishing apparatus including a plurality of the eddy current sensors, and an input of the machine learning model is data after the preprocessing is executed on an output signal at each position facing the target substrate in a plurality of cycles of polishing-table rotation of the plurality of the eddy current sensors.

With this configuration, by using the output signals of the plurality of times of circling, even if the movement loci of the eddy current sensor based on the substrate are different for each time of circling of the specific eddy current sensor, the influence can be offset, so that the estimation accuracy of the metal line height can be improved. By using a plurality of output signals of the eddy current sensors in the same circling, even if noise is placed on one output signal, if no noise is placed on the other output signals, the metal line height can be estimated, so that the robustness of estimation of the metal line height can be improved.

A polishing apparatus according to a seventh aspect of the present invention is the polishing apparatus according to any one of the first to fourth aspects, in which an input of the machine learning model is data after the preprocessing is executed on an output signal at each position facing the target substrate in a plurality of cycles of polishing-table rotation of the plurality of the one eddy current sensor.

With this configuration, by using the output signals of the plurality of times of circling, even if the movement loci of the eddy current sensor based on the substrate are different for each time of circling of the specific eddy current sensor, the influence can be offset, so that the estimation accuracy of the metal line height can be improved.

A polishing apparatus according to an eighth aspect of the present invention is the polishing apparatus according to any one of the first to seventh aspects, in which the processor causes the learned machine learning model to relearn using an output signal of an eddy current sensor during polishing processing.

With this configuration, even after the polishing apparatus is operated, since relearning is performed using the output signal of the eddy current sensor during polishing processing, the prediction accuracy of the metal line height can be improved.

An information processing system according to a ninth aspect of the present invention includes: a preprocessing unit configured to generate preprocessed data on a target substrate by executing predetermined preprocessing on an output signal when an eddy current sensor is at each position facing a target substrate during polishing processing of a target substrate; and a prediction unit configured to determine a metal line height at at least one position of the target substrate by inputting preprocessed data on the target substrate to a learned machine learning model using a learning data set in which data after predetermined preprocessing is executed on an output signal when the eddy current sensor is at each position facing a substrate is set as an input and a metal line height at at least one position of the substrate is set as an output.

With this configuration, the metal line height at at least one position of the target substrate by inputting the preprocessed data on the target substrate to the learned machine learning model using the learning data set in which the data after the predetermined preprocessing is executed on the output signal when the eddy current sensor is at each position facing the substrate is set as an input and the metal line height at the at least one position of the substrate is set as an output can be estimated.

An information processing method according to a tenth aspect of the present invention has: a preprocessing step of generating preprocessed data on a target substrate by executing predetermined preprocessing on an output signal when an eddy current sensor is at each position facing a target substrate during polishing processing of a target substrate; and a prediction step of determining a metal line height at at least one position of the target substrate by inputting preprocessed data on the target substrate to a learned machine learning model using a learning data set in which data after predetermined preprocessing is executed on an output signal when the eddy current sensor is at each position facing a substrate is set as an input and a metal line height at at least one position of the substrate is set as an output.

With this configuration, the metal line height at at least one position of the target substrate by inputting the preprocessed data on the target substrate to the learned machine learning model using the learning data set in which the data after the predetermined preprocessing is executed on the output signal when the eddy current sensor is at each position facing the substrate is set as an input and the metal line height at the at least one position of the substrate is set as an output can be estimated.

A program according to an eleventh aspect of the present invention is a program for causing a computer to function as: a preprocessing unit configured to generate preprocessed data on a target substrate by executing predetermined preprocessing on an output signal when an eddy current sensor is at each position facing a target substrate during polishing processing of a target substrate; and a prediction unit configured to determine a metal line height at at least one position of the target substrate by inputting preprocessed data on the target substrate to a learned machine learning model using a learning data set in which data after predetermined preprocessing is executed on an output signal when the eddy current sensor is at each position facing a substrate is set as an input and a metal line height at at least one position of the substrate is set as an output.

With this configuration, the metal line height at at least one position of the target substrate by inputting the preprocessed data on the target substrate to the learned machine learning model using the learning data set in which the data after the predetermined preprocessing is executed on the output signal when the eddy current sensor is at each position facing the substrate is set as an input and the metal line height at the at least one position of the substrate is set as an output can be estimated.

### Advantageous Effects of Invention

According to one aspect of the present invention, the metal line height at at least one position of the target substrate by inputting the preprocessed data on the target substrate to the learned machine learning model using the learning data set in which the data after the predetermined preprocessing is executed on the output signal when the eddy current sensor is at each position facing the substrate is set as an input and the metal line height at the at least one position of the substrate is set as an output can be estimated.

### BRIEF DESCRIPTION OF DRAWINGS

FIG. 1 is a schematic front view of a polishing apparatus according to an embodiment.

FIG. 2 is a diagram for illustrating a metal line height according to the present embodiment.

FIG. 3A is a schematic diagram illustrating a horizontal movement locus of the eddy current sensor 150 with respect to the substrate 121.

FIG. 3B is a graph representing the output signal of the eddy current sensor 150 while the eddy current sensor 150 passes under the substrate 121.

FIG. 4 is a functional block diagram of a processor 142 according to a first embodiment.

FIG. 5 is a schematic diagram illustrating an example of a neural network used in the first embodiment.

FIG. 6 is a flowchart illustrating an example of a flow of processing according to the first embodiment.

FIG. 7 is a functional block diagram of the processor 142 according to a modified example of the first embodiment.

FIG. 8 is a flowchart illustrating an example of a flow of processing according to the modified example of the first embodiment.

FIG. 9A is a schematic diagram illustrating horizontal movement loci of the plurality of eddy current sensors with respect to the substrate 121.

FIG. 9B is a schematic diagram of a graph representing the output signal of each eddy current sensor while each eddy current sensor passes under the substrate 121.

FIG. 10 is a functional block diagram of the processor 142 according to a second embodiment.

FIG. 11 is a schematic diagram illustrating an example of a neural network used in the second embodiment.

FIG. 12 is a schematic diagram illustrating an example of output signals of the same eddy current sensor from the V th rotation to the V+3 th rotation.

FIG. 13 is a schematic view illustrating horizontal movement loci at the horizontal position of the same eddy current sensor from a V th rotation to a V+3 th rotation in FIG. 12.

FIG. 14 is a functional block diagram of the processor 142 according to a third embodiment.

FIG. 15 is a schematic diagram illustrating an example of a flow of data at the time of learning of the neural network used in the third embodiment.

FIG. 16 is a schematic diagram illustrating an example of a neural network used in the third embodiment.

FIG. 17 is a schematic diagram illustrating an example of a flow of data at the time of inference of the neural network used in the third embodiment.

### DESCRIPTION OF EMBODIMENTS

Hereinafter, each embodiment will be described with reference to the drawings. However, a detailed description more than necessary may be omitted. For example, a detailed description of a well-known matter and a redundant description of substantially the same configuration may be omitted. This is to avoid unnecessary redundancy of the following description and to facilitate understanding of those skilled in the art.

In the present embodiment, a machine learning model (here, a neural network as an example) is caused to learn an output signal obtained by measuring a wafer having a wiring pattern with an eddy current sensor during CMP polishing and a metal line height (it may be a measured value or an estimated value.) when the output signal is measured. By applying this learned machine learning model (here, a neural network as an example) to the output signal obtained during the CMP processing, the estimated metal line height is determined (that is, the film thickness value is estimated). In addition, the estimation accuracy is improved by relearning the learned machine learning model using the eddy current waveform data during the CMP processing and the estimated metal line height obtained during the operation.

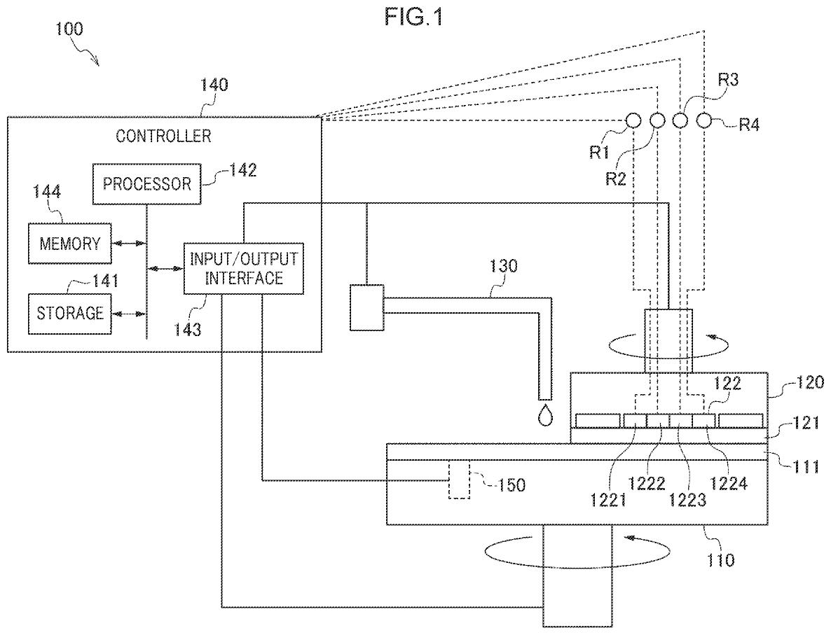

FIG. 1 is a schematic front view of a polishing apparatus according to an embodiment. The polishing apparatus 100 according to an embodiment is a CMP apparatus that polishes a substrate by chemical mechanical polishing (CMP). It should be noted that the polishing apparatus 100 has only to be an apparatus that polishes a substrate by rotating a polishing table provided with an eddy current sensor.

As illustrated in FIG. 1, the polishing apparatus 100 according to an embodiment includes a polishing table 110, a polishing head 120, and a liquid supply mechanism 130. The polishing apparatus 100 may further include a controller 140 for controlling each component. The controller 140 may include, for example, a storage 141, a processor 142, and an input/output interface 143.

A polishing pad 111 is detachably attached to a surface facing the polishing head 120 of the polishing table 110. The polishing head 120 is provided so as to face the polishing table 110. A substrate 121 is detachably attached to a surface facing the polishing table 110 of the polishing head 120. The liquid supply mechanism 130 is configured to supply polishing liquid such as slurry to the polishing pad 111. It should be noted that the liquid supply mechanism 130 may be configured to supply a cleaning liquid, a chemical solution, or the like in addition to the polishing liquid.

The polishing apparatus 100 can bring the substrate 121 into contact with the polishing pad 111 by lowering the polishing head 120 with a vertical movement mechanism (not illustrated). However, the vertical movement mechanism may vertically move the polishing table 110. The polishing table 110 and the polishing head 120 are rotated by a motor (not illustrated) or the like. The polishing apparatus 100 polishes the substrate 121 by rotating both the polishing table 110 and the polishing head 120 in a state where the substrate 121 and the polishing pad 111 are in contact with each other.

An eddy current sensor 150 is provided inside the polishing table 110. Specifically, for example, the eddy current sensor 150 is installed at a position passing through the center of the substrate 121 during being polished. The eddy current sensor 150 induces eddy currents in the conductive layer on the surface of the substrate 121. The eddy current sensor 150 further detects the thickness (hereinafter, also referred to as a metal line height) of the conductive layer on the surface of the substrate 121 from a change in impedance caused by the magnetic field generated by the eddy current. The eddy current sensor 150 (or an operator reading the output of the controller 140 connected to the eddy current sensor 150 or the eddy current sensor 150) can detect the end point of substrate polishing from the detected thickness of the conductive layer. The input/output interface 143 is connected to the eddy current sensor 150 and receives an output signal detected by the eddy current sensor 150 from the eddy current sensor 150.

The polishing head is provided with an airbag for pressing the substrate 121, and the airbag 122 is divided into, for example, a plurality of sections 1221 to 1224. The airbag 122 is provided in the polishing head 120 as an example. It should be noted that in addition to or instead of it, the airbag 122 may be provided on the polishing table 110. The airbag 122 is a member for adjusting the polishing pressure of the substrate 121 for each region of the substrate 121. The airbag 122 is configured so that a volume thereof is changed by a pressure of air introduced inside. It should be noted that although the name is “air” bag, a fluid other than air, for example, nitrogen gas or pure water may be introduced into the airbag 122.

The sections 1221, 1222, 1223, and 1224 are respectively connected to the corresponding pressure control valves R1, R2, R3, and R4. The pressure control valves R1, R2, R3, and R4 are connected to the controller 140, and individually adjust the pressures of the pressure fluids (for example, gas) to be supplied to the sections 1221, 1222, 1223, and 1224 according to a control signal from the controller 140. Thus, the pressure can be adjusted for each of the sections 1221 to 1224.

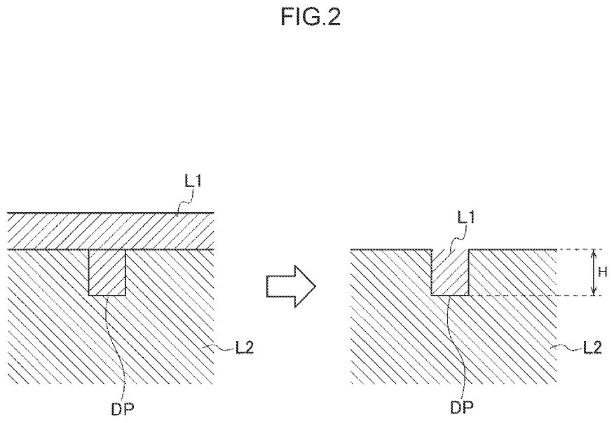

FIG. 2 is a diagram for illustrating a metal line height according to the present embodiment. As illustrated in the cross-sectional view of the substrate on the left side in FIG. 2, the substrate before polishing has a base layer L12 in which a wiring groove DP is formed and a metal layer L11 provided on the base layer L12. Here, the base layer L2 is, for example, an oxide film (for example, SiO₂) or a nitride film. Subsequently, when the metal layer L11 is polished by the polishing apparatus 100 to be scraped, and the metal placed on the base layer L12 other than the groove DP is removed, the cross-sectional view of the substrate on the right side in FIG. 2 is obtained. Here, as illustrated in FIG. 2, the length H from the bottom of the groove DP to the upper surface of the metal layer L11 is the metal line height. Hereinafter, the substrate 121 will be described as a wafer as an example.

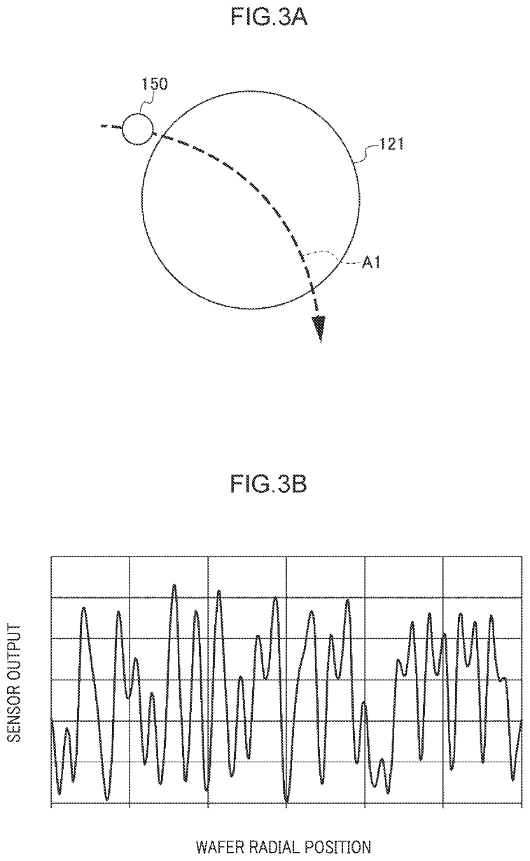

FIG. 3A is a schematic diagram illustrating a horizontal movement locus of the eddy current sensor 150 with respect to the substrate 121. As illustrated in FIG. 3A, rotation of the polishing table 110 causes the eddy current sensor 150 to pass under the substrate 121 in a locus indicated by an arrow A1. Since the rotation speed of the polishing table 110 is determined in advance, the speed of the eddy current sensor 150 fixed to the polishing table 110 is known. The positions of the eddy current sensor 150 and the substrate 121 of the polishing head 120 are set in advance so that the eddy current sensor 150 passes through the center of the substrate 121 (here, a wafer as an example). Thus, since the eddy current sensor 150 moves in an arc shape at a constant speed, the processor 142 can calculate a position to which the eddy current sensor 150 moves, for example, for each predetermined time, and can calculate a radial position of the wafer (hereinafter, referred to as a wafer radial position) from this position.

FIG. 3B is a graph representing the output signal of the eddy current sensor 150 while the eddy current sensor 150 passes under the substrate 121. The horizontal axis represents the wafer radial position where the eddy current sensor 150 is positioned, and the vertical axis represents the sensor output. Here, the sensor output when the radius of the wafer is 150 mm and the wafer radial position changes from −150 mm to 150 mm is illustrated. As described above, the waveform of the output signal has irregularities.

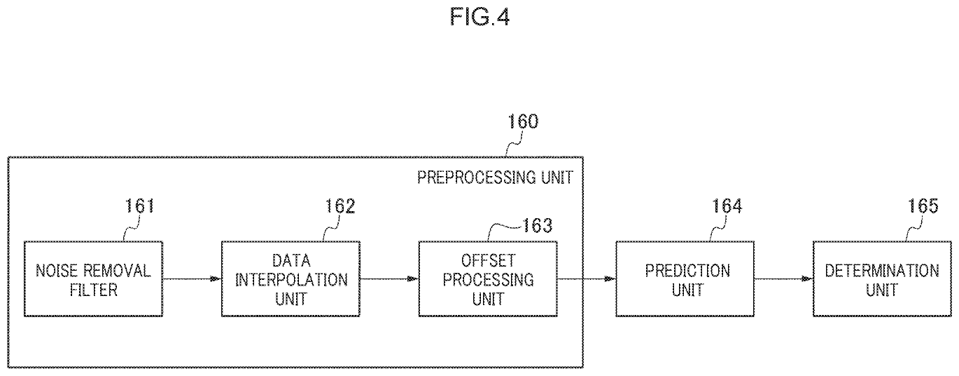

FIG. 4 is a functional block diagram of the processor 142 according to the first embodiment. As illustrated in FIG. 4, the processor 142 functions as a preprocessing unit 160, a prediction unit 164, and a determination unit 165.

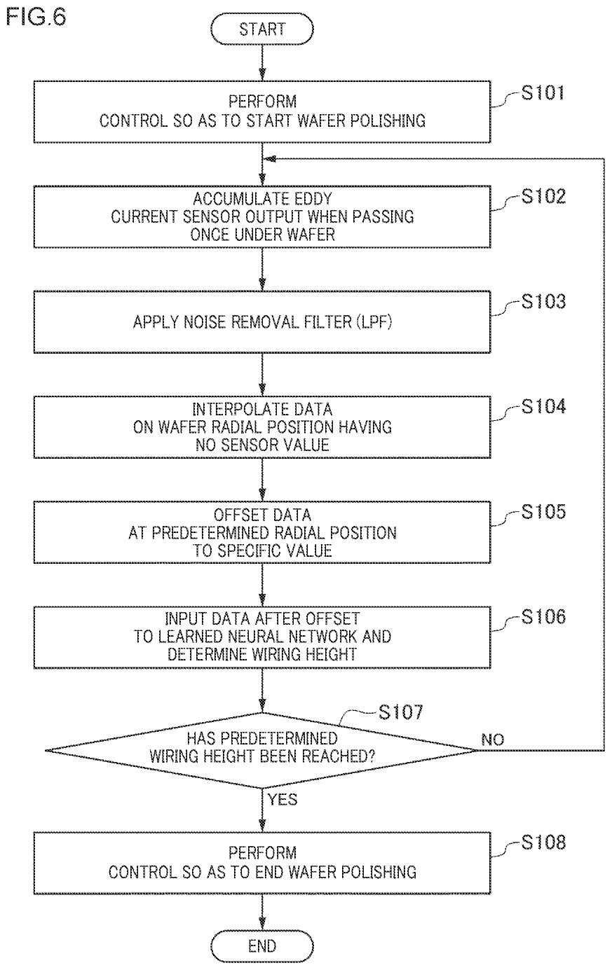

During the polishing processing of the target substrate, the preprocessing unit 160 performs predetermined preprocessing on the output signal when the eddy current sensor 150 is at each position facing the target substrate to generate preprocessed data on the target substrate. Here, the preprocessing unit 160 includes a noise removal filter 161, a data interpolation unit 162, and an offset processing unit 163. These pieces of processing will be described below with reference to FIG. 6.

The prediction unit 164 determines the metal line height of the target substrate using a machine learning model (here, a neural network as an example). More specifically, the prediction unit 164 determines the metal line height at at least one position (here, M positions as an example) of the target substrate by inputting the preprocessed data on the target substrate to the learned machine learning model (here, a neural network as an example) using the learning data set in which the data after the predetermined preprocessing is executed on the output signal when the eddy current sensor 150 is at each position facing the substrate is set as an input and the metal line height at at least one position of the substrate is set as an output.

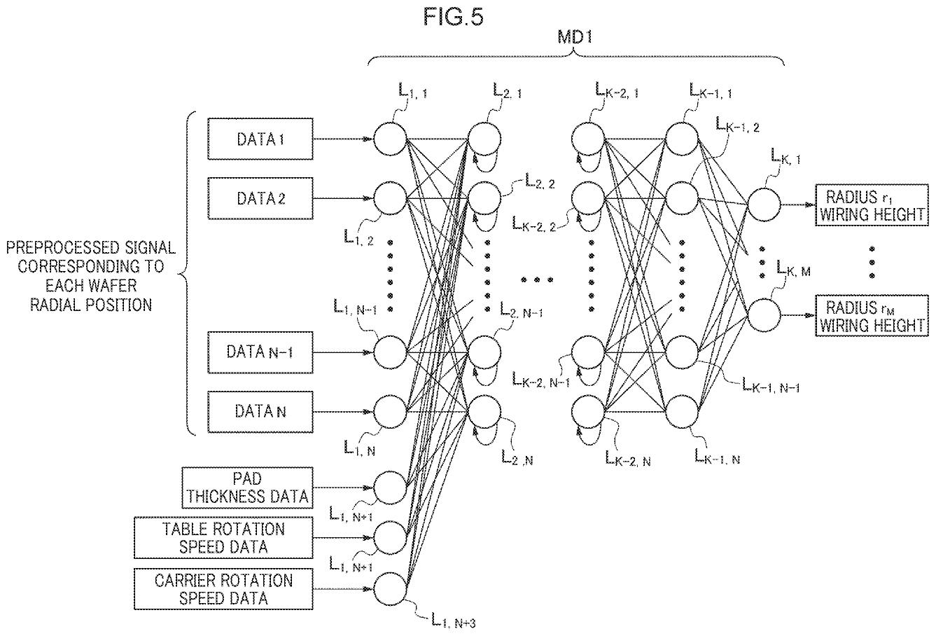

FIG. 5 is a schematic diagram illustrating an example of a neural network used in the first embodiment. As illustrated in FIG. 5, as an example, the neural network MD1 is a K layer (K is a natural number) neural network, the input layer has N+3 (N is a natural number) neurons, the intermediate layer has N neurons, and the output layer has M (M is a natural number) neurons. Each neuron included in the input layer and the intermediate layer is fully connected to a neuron in the next layer, as an example. In addition, the neuron in the intermediate layer performs feedback by weighting the input with its own output, as an example. As described above, the neural network according to the present embodiment is a recurrent neural network (RNN) as an example.

The output waveform or the waveform pattern appearing in the output signal of the eddy current sensor 150 during passing under the substrate at a certain circling is related to an output waveform of the output signal (also referred to as the output signal of the previous scan) of the eddy current sensor 150 during passing under the circling substrate before the certain circling. In order to allow the data on the output signal of the previous scan to be used, the machine learning model preferably uses a recurrent neural network (RNN) or a long short-term memory (LSTM) being a type of the recurrent neural network.

Data 1 to data N being preprocessed signals corresponding to the respective wafer radial positions are input to the neurons L_{1,1} to L_{1,N} in the input layer of the neural network. In addition, thickness data on the polishing pad 111 (hereinafter, also referred to as pad thickness data), rotation speed data on the polishing table 110 (hereinafter, also referred to as table rotation speed data), and rotation speed data on the polishing head 120 (hereinafter, also referred to as carrier rotation speed data) are respectively input to the neurons L_{1,N+1} to L_{1,N+3} in the input layer of the neural network. The respective metal line heights at the radii r₁ to r_{M} are output from the output layer of the neural network.

That is, at the time of learning of the neural network, as the learning data set, the data 1 to the data N being preprocessed signals corresponding to the respective wafer radial positions, the pad thickness data, the table rotation speed data, and the carrier rotation speed data are input as the input data; the measured values or the estimated values of the metal line heights at the radius r₁ to the radius r_{M} at that time are input as the output data; and the weighting factor of each neuron is updated. Here, the measurement value is a metal line height measured after the wafer is actually polished. An existing update method (for example, back propagation or the like) may be used to update the weighting factor.

Subsequently, a flow of processing according to the present embodiment will be described with reference to FIG. 6. FIG. 6 is a flowchart illustrating an example of a flow of processing according to the first embodiment. Here, the description will be given assuming that the storage 141 stores the weighting factor of each neuron in the learned neural network.

(Step S101) First, the processor 142 performs control so that wafer polishing is started.

(Step S102) Next, the processor 142 sequentially accumulates the output signal of the eddy current sensor when passing once under the wafer in the storage 141.

The following processing in steps S103 to S105 is processing of the preprocessing unit 160.

(Step S103) Next, the noise removal filter 161 applies a noise removal filter (here, a low-pass filter (LPF) as an example) to the output signal of the eddy current sensor.

(Step S104) Next, the data interpolation unit 162 interpolates the data on the wafer radial position having no sensor value.

(Step S105) Next, the offset processing unit 163 offsets the data at the predetermined radial position to a specific value with respect to the data-interpolated signal. Thus, it is possible to perform cancelling by setting the DC component varying for each wafer to the same specific value, and it is possible to learn the difference in the AC component excluding the DC component. The offset processing unit 163 may be, for example, a filter that removes a DC component.

(Step S106) Next, the prediction unit 164 refers to the storage 141, inputs the data after the offset to the learned neural network, and determines the metal line height.

(Step S107) Next, the determination unit 165 determines whether the metal line height determined in step S106 has reached a predetermined metal line height. If it is determined that the metal line height has not reached the predetermined metal line height, the processing returns to step S102, and the processing in and after step S102 is executed.

(Step S108) If it is determined in step S107 that the metal line height has reached the predetermined metal line height, the processor 142 performs control to end wafer polishing.

As described above, if the determined metal line height has reached the predetermined metal line height, the processor 142 performs control to finish polishing of the target substrate. Thus, the polishing can be automatically terminated when the predetermined metal line height has been reached.

It should be noted that in the first embodiment, the neural network outputs the metal line heights at a plurality of positions of the substrate, but the present invention is not limited thereto, and the metal line height at one position of the substrate may be output.

As described above, the polishing apparatus according to the first embodiment includes: a polishing table 110 provided with the eddy current sensor 150 and configured to be rotatable, a polishing head 120 facing the polishing table 110, configured to be rotatable, and having a surface facing the polishing table 110 to which a substrate can be attached, and a processor 142. During the polishing processing of the target substrate, the processor 142 performs predetermined preprocessing on the output signal when the eddy current sensor is at each position facing the target substrate to generate preprocessed data on the target substrate. Then, the processor 142 determines the metal line height at at least one position of the target substrate by inputting the preprocessed data on the target substrate to the learned machine learning model using the learning data set in which the data after the predetermined preprocessing is executed on the output signal when the eddy current sensor 150 is at each position facing the substrate is set as an input and the metal line height at at least one position of the substrate is set as an output.

With this configuration, the metal line height at at least one position of the target substrate by inputting the preprocessed data on the target substrate to the learned machine learning model using the learning data set in which the data after the predetermined preprocessing is executed on the output signal when the eddy current sensor 150 is at each position facing the substrate is set as an input and the metal line height at the at least one position of the substrate is set as an output can be estimated.

It should be noted that the input of the neural network according to the present embodiment includes the thickness of the polishing pad, the rotation speed of the polishing table, and the rotation speed of the polishing head, but is not limited thereto, and one or two of them may be included. That is, the input of the machine learning model may further include the thickness of the polishing pad, the rotation speed of the polishing table, and/or the rotation speed of the polishing head. With this configuration, since the amount of one scraping can be changed depending on the thickness of the polishing pad, the rotation speed of the polishing table, and/or the rotation speed of the polishing head, considering one or more of these parameters allows the estimation accuracy of the metal line height to be improved.

In addition, a neural network having no input of the thickness of the polishing pad, the rotation speed of the polishing table, and the rotation speed of the polishing head may be used.

### Modified Example of First Embodiment

Subsequently, a modified example of the first embodiment will be described. The modified example of the first embodiment is different from the first embodiment in that the processor 142 further controls the pressure distribution in the airbag 122 according to the distribution of the determined metal line height.

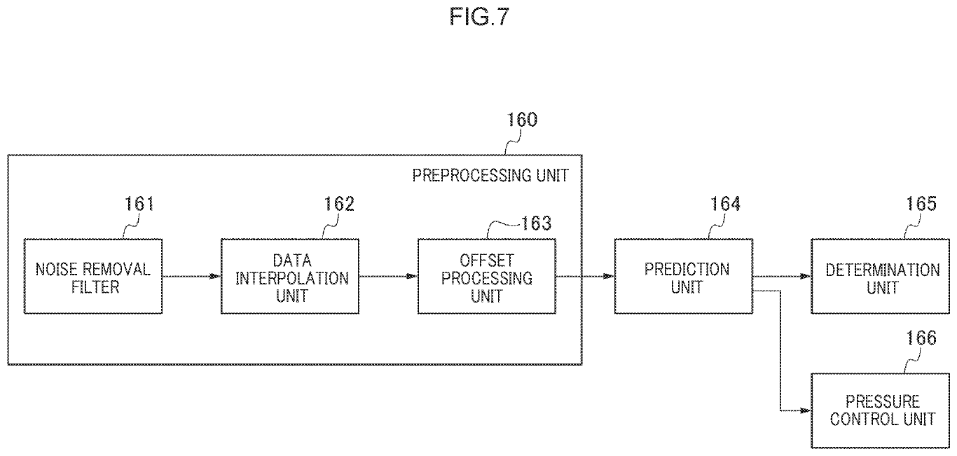

FIG. 7 is a functional block diagram of the processor 142 according to a modified example of the first embodiment. The functional block diagram of the processor 142 according to the modified example of the first embodiment illustrated in FIG. 7 is different from the functional block diagram of the processor 142 according to the first embodiment illustrated in FIG. 4 in that a pressure control unit 166 is added. In FIG. 7, the same elements as those in FIG. 4 are denoted by the same reference numerals, and the description thereof will be omitted. The pressure control unit 166 controls the pressure distribution in the airbag 122 according to the distribution of the metal line height determined by the prediction unit 164.

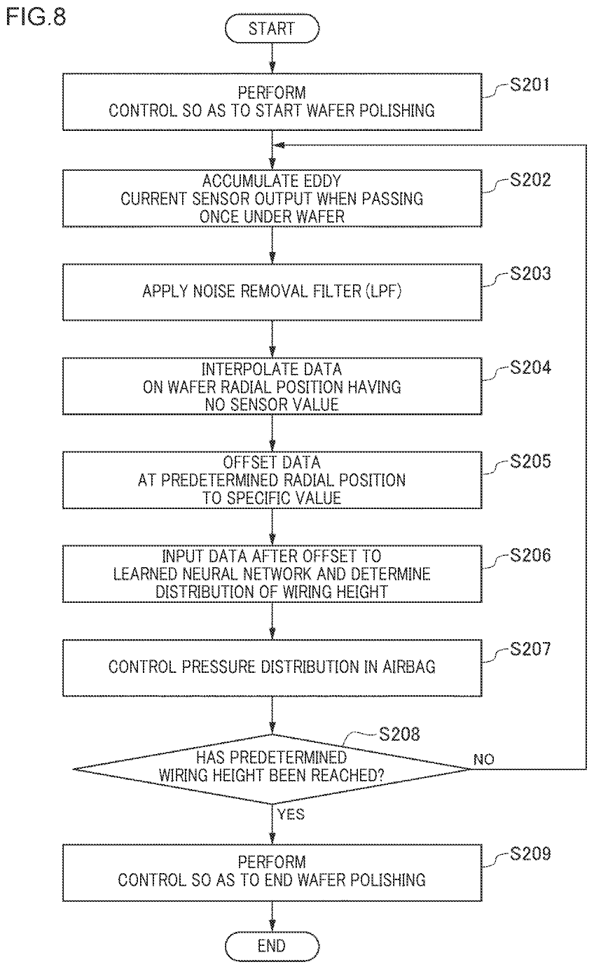

FIG. 8 is a flowchart illustrating an example of a flow of processing according to the modified example of the first embodiment. Since steps S201 to S205 are the same as steps S101 to S105 in FIG. 6, the description thereof will be omitted.

(Step S206) The prediction unit 164 refers to the storage 141, inputs the data after the offset to the learned neural network, and determines the distribution of the metal line height.

(Step S207) Next, the pressure control unit 166 controls the pressure distribution in the airbag 122 according to the distribution of the metal line height determined by the prediction unit 164. Specifically, for example, when the metal line height at the target position is higher than those at the other positions, the metal line height is less scraped than those at the other positions, and thus, the pressure control unit 166 may set the pressure in the airbag 122 at the position to be higher than those at the other positions. In addition, in addition to or instead of it, when the metal line height at the target position is lower than those at the other positions, the metal line height is more scraped than those at the other positions, and thus, the pressure control unit 166 may set the pressure in the airbag 122 at the position to be lower than those at the other positions. Thus, the uniformity of the height (for example, the metal line height) of the polished surface of the substrate can be improved.

Since the subsequent steps S208 to S209 are the same as steps S107 to S108 in FIG. 6, the description thereof will be omitted.

### Second Embodiment

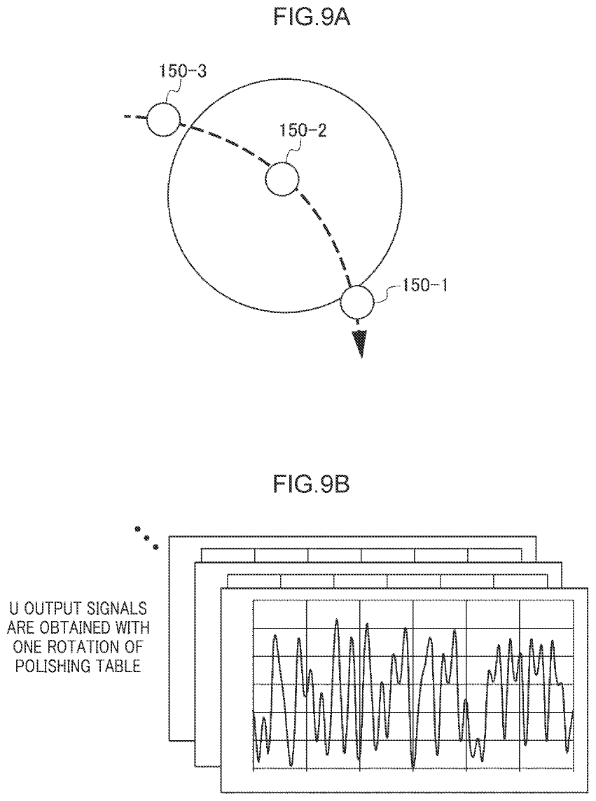

Subsequently, the second embodiment will be described. The second embodiment is different from the first embodiment in that a plurality of eddy current sensors are provided. FIG. 9A is a schematic diagram illustrating horizontal movement loci of the plurality of eddy current sensors with respect to the substrate 121. As illustrated in FIG. 9A, U eddy current sensors of eddy current sensors 150-1, . . . , and 150-U (U is an integer of 2 or more) are provided.

FIG. 9B is a schematic diagram of a graph representing the output signal of each eddy current sensor while each eddy current sensor passes under the substrate 121. As illustrated in FIG. 9B, since the respective output signals of the eddy current sensors 150-1, . . . , and 150-U are obtained every time the polishing table 110 makes one rotation, U output signals are obtained.

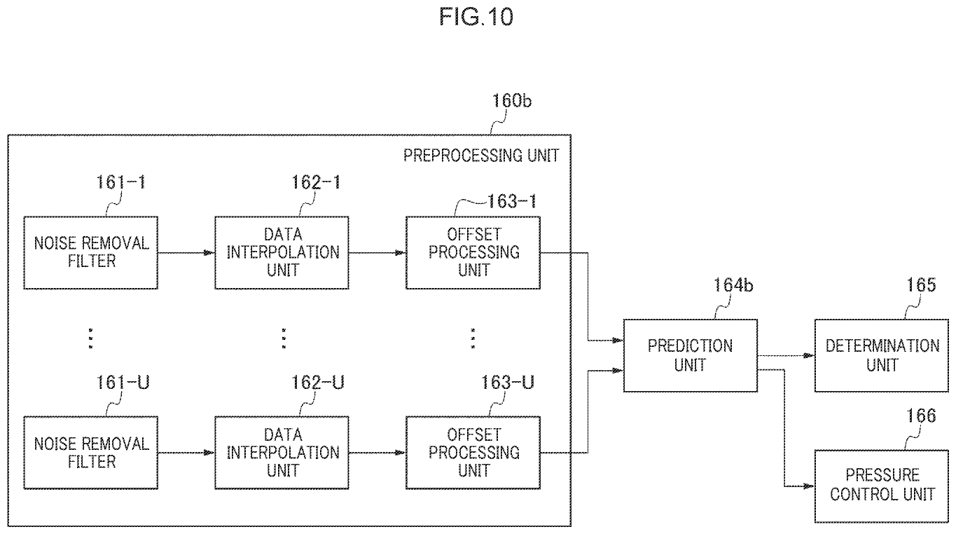

FIG. 10 is a functional block diagram of the processor 142 according to the second embodiment. As illustrated in FIG. 10, as compared with the modified example of the first embodiment in FIG. 7, the preprocessing unit 160 is changed to a preprocessing unit 160b, and the prediction unit 164 is changed to a prediction unit 164b.

The preprocessing unit 160b includes noise removal filters 161-1, . . . , and 161-U, data interpolation units 162-1, . . . , and 162-U, and offset processing units 163-1, . . . , and 163-U. The noise removal filters 161-1, . . . , and 161-U respectively apply noise removal filters to the output signals from the corresponding eddy current sensors 150-1, . . . , and 150-U. Each of the data interpolation units 162-1, . . . , and 162-U interpolates data on a wafer radial position having no sensor value into the corresponding noise-removal-filtered signal. Each of the offset processing units 163-1, . . . , and 163-U offsets the data at the predetermined radial position to a specific value with respect to the corresponding data-interpolated signal.

The prediction unit 164b determines the metal line height of the target substrate using a machine learning model (here, a neural network as an example). More specifically, the prediction unit 164b determines the metal line height at at least one position (here, M positions as an example) of the target substrate by inputting the preprocessed data of the target substrate to a machine learning model (here, a neural network as an example) learned using a learning data set in which the data after execution of predetermined preprocessing on the output signal at each position facing the target substrate of the same polishing-table rotation-circling of the plurality of eddy current sensors 150-1 to 150-U is set as an input and the metal line height at at least one position of the substrate is set as an output.

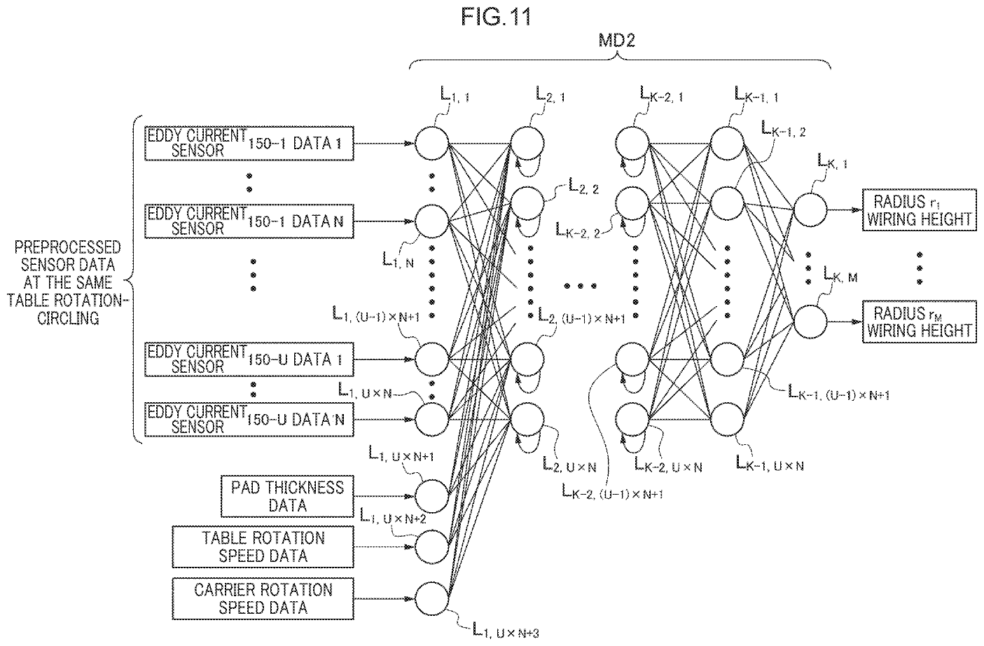

FIG. 11 is a schematic diagram illustrating an example of a neural network used in the second embodiment. As illustrated in FIG. 11, as an example, the neural network MD2 is a K layer (K is a natural number) neural network, the input layer has U×N+3 (N is a natural number) neurons, the intermediate layer has U×N neurons, and the output layer has M (M is a natural number) neurons. Each neuron included in the input layer and the intermediate layer is fully connected to a neuron in the next layer, as an example. In addition, the neuron in the intermediate layer performs feedback by weighting the input with its own output.

The neurons L_{1,1} to L_{1,U×N} of the input layer of the neural network are input with data 1 to N of the eddy current sensor 150-1, . . . , and data 1 to N of the eddy current sensor 150-U which are signals corresponding to the respective wafer radial positions after preprocessing is performed on the output signals from the eddy current sensors 150-1, . . . , and 150-U at the same table rotation-circling.

In addition, thickness data on the polishing pad 111 (pad thickness data), rotation speed data on the polishing table 110 (table rotation speed data), and rotation speed data on the polishing head 120 (carrier rotation speed data) are respectively input to the neurons L_{1,U×N+1} to L_{1,U×N+3} in the input layer of the neural network. The respective metal line heights at the radii r₁ to r_{M} are output from the output layer of the neural network.

As described above, in the second embodiment, a plurality of eddy current sensors are provided, and the input of the machine learning model is data after the preprocessing is executed on the output signal at each position facing the target substrate at the same polishing-table rotation-circling of the plurality of eddy current sensors 150-1 to 150-U.

Thus, the data after the preprocessing is executed on the output signals in the same polishing-table rotation-circling of the plurality of eddy current sensors is used as the input of the machine learning model, so that even if noise is placed on one output signal, if no noise is placed on the other output signals, the metal line height can be estimated by using a plurality of output signals in the same circling. Thus, robustness of estimation of the metal line height can be improved.

### Third Embodiment

Subsequently, the third embodiment will be described. The third embodiment and the second embodiment are in common in that output signals of a plurality of eddy current sensors are used, but the third embodiment is different from the second embodiment in that output signals of a plurality of times of circling are further used.

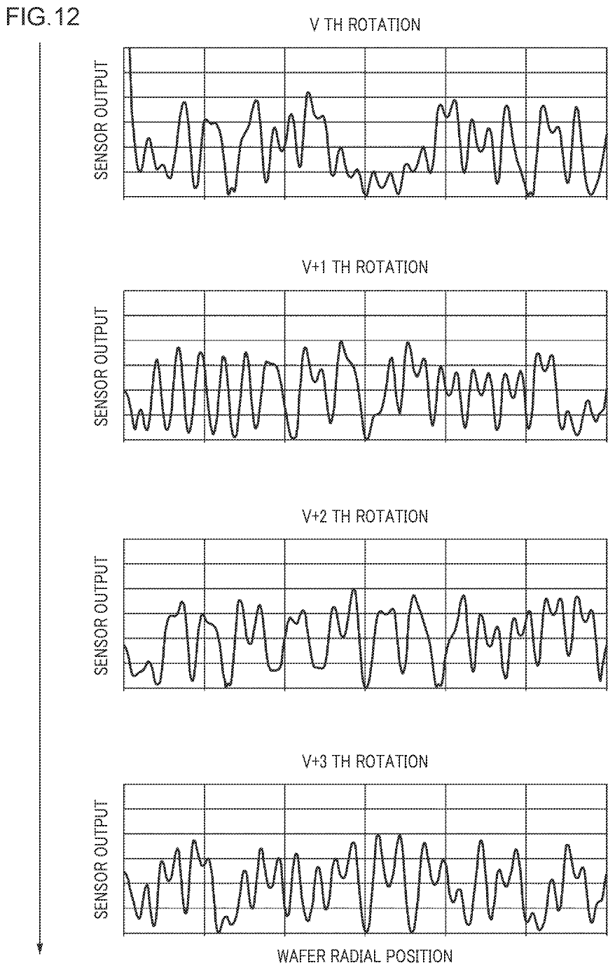

FIG. 12 is a schematic diagram illustrating an example of output signals of the same eddy current sensor from the V th rotation to the V+3 th rotation of the polishing table. V is a natural number. The vertical axis represents the sensor output, and the horizontal axis represents the wafer radial position. As the number of times of polishing increases, the metal line height decreases little by little by polishing.

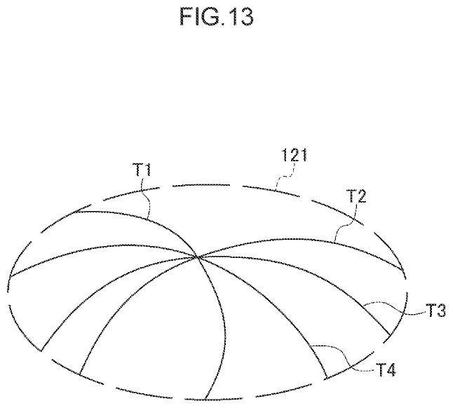

FIG. 13 is a schematic diagram illustrating horizontal movement loci, with respect to the substrate, of the same eddy current sensor from the V th rotation to the V+3 th rotation in FIG. 12. As illustrated in FIG. 13, the horizontal movement loci of the V th rotation to the V+3 th rotation of the eddy current sensor are respectively T1 to T4. As described above, even with the same eddy current sensor, the horizontal movement loci with respect to the substrate 121 is different for each number of times of rotation of the polishing table. In the present embodiment, the average metal line height of the plurality of times of circling is estimated by using the output signals of the plurality of times of circling of the plurality of eddy current sensors.

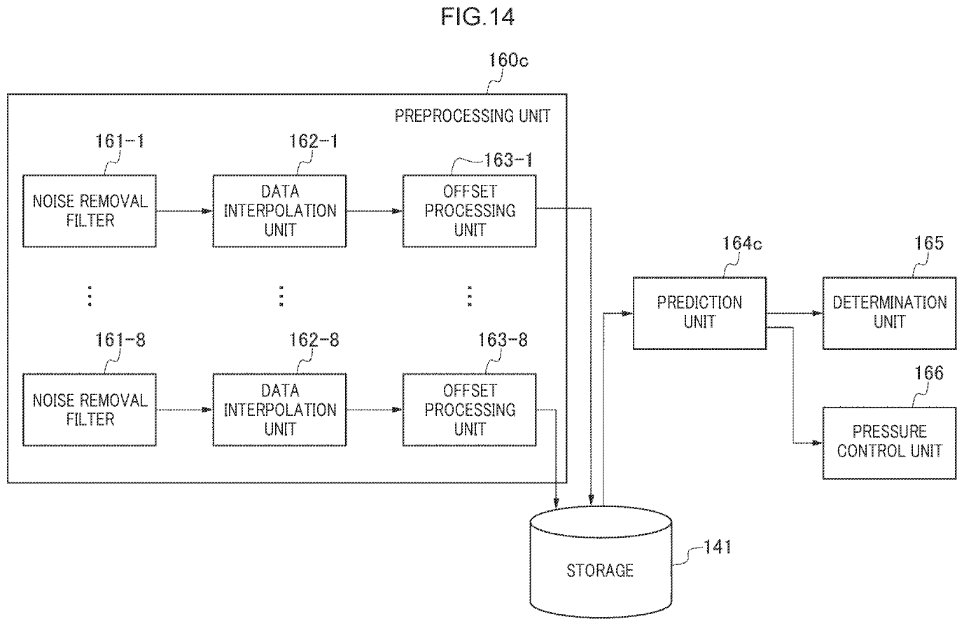

FIG. 14 is a functional block diagram of the processor 142 according to the third embodiment. As illustrated in FIG. 14, as compared with the second embodiment in FIG. 10, the preprocessing unit 160b is changed to a preprocessing unit 160c, and the prediction unit 164b is changed to a prediction unit 164c.

In the present embodiment, as an example, eight eddy current sensors of the eddy current sensors 150-1, . . . , and 150-8 are provided. In accordance with this, the preprocessing unit 160c is obtained by changing the number of noise removal filters, the number of data interpolation units, and the number of offset processing units in the preprocessing unit 160b to 8. The noise removal filters 161-1 to 161-8, the data interpolation units 162-1 to 162-8, and the offset processing units 163-1 to 163-8 execute processing similar to those of the second embodiment. Then, the offset processing units 163-1 to 163-8 store the data after offset in the storage 141.

The prediction unit 164c determines the metal line height of the target substrate using a machine learning model (here, a neural network as an example). More specifically, the prediction unit 164c determines the metal line height at at least one position (here, M positions as an example) of the target substrate by inputting the preprocessed data of the target substrate to a machine learning model (here, a neural network as an example) learned using a learning data set in which the data after execution of predetermined preprocessing on the output signal at each position facing the target substrate of the same “plurality of” cycles of polishing-table rotation of the plurality of eddy current sensors is set as an input and the metal line height at at least one position of the substrate is set as an output.

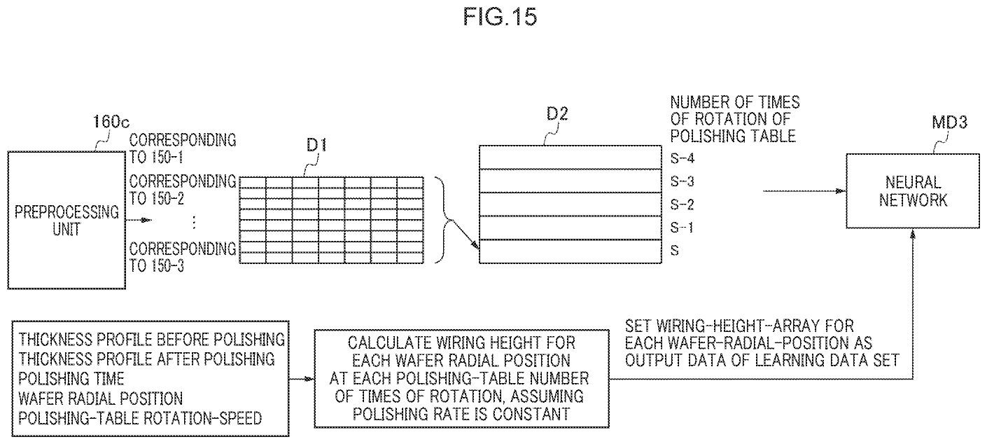

FIG. 15 is a schematic diagram illustrating an example of a flow of data at the time of learning of the neural network used in the third embodiment. As illustrated in FIG. 15, every time the polishing table makes one rotation, data D1 after the preprocessing unit 160c executes preprocessing on the output signal output from each of the eddy current sensors 150-1 to 150-8 is output and stored in the storage 141. Since data on each wafer radial position is obtained for each of the eddy current sensors 150-1 to 150-8, the data D1 for one rotation of the polishing table is represented by a matrix of 8 rows×N columns (N is a natural number) as an example as illustrated in FIG. 15. Here, as an example, since the wafer radial position ranges from −150 mm to 150 mm, when the column index is 1, data of the wafer radial position of −150 mm is represented, and when the column index is N, data of the wafer radial position of 150 mm is represented.

Data after preprocessing in which the number of times of rotation of the polishing table (hereinafter, also referred to as the number of times of rotation of the polishing table) is five rotations is used as input data on a learning data set of the neural network MD3 used in the third embodiment. In FIG. 15, the data D2 after the preprocessing of five times in which the number of times of rotation of the polishing table is S-4 to S (S is an integer of 5 or more) is input as input data on the learning data set of the neural network MD3.

First, a thickness distribution of the substrate before polishing (also referred to as a thickness profile before polishing) is measured. Then, the polishing time and the polishing table rotation speed are set. Then, the polishing is executed with the set polishing time and the set polishing table rotation speed. After completion of polishing, a thickness distribution of the substrate after polishing (also referred to as a thickness profile after polishing) is measured.

Assuming that the polishing rate, which is the thickness to be removed by polishing per rotation of the polishing table 110, is constant, the metal line height for each wafer radial position at each of the numbers of times S-4 to S of rotation of the polishing table is calculated. The metal line height array for each wafer radial position obtained by this calculation is set as output data of the learning data set.

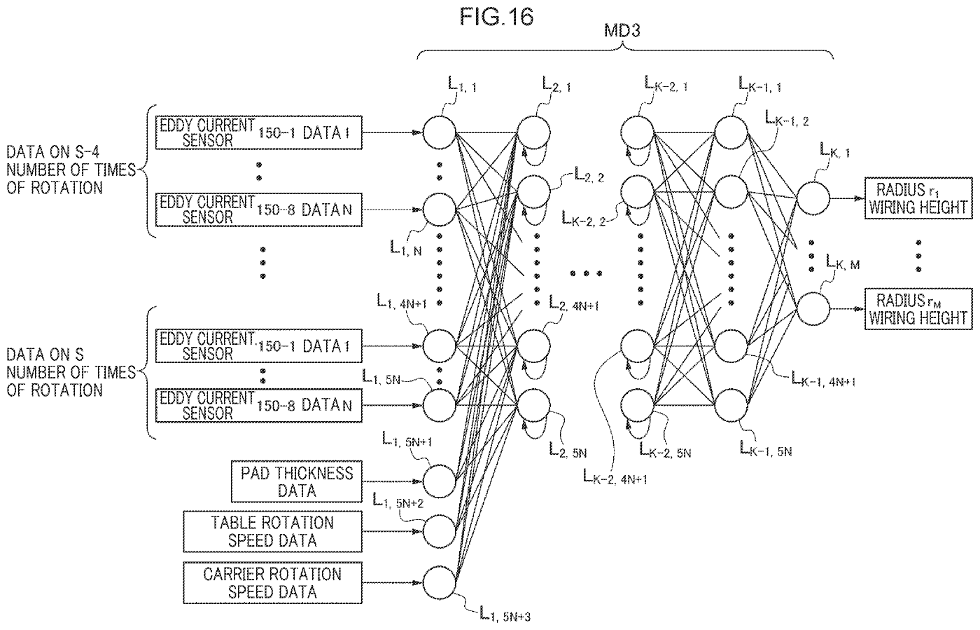

FIG. 16 is a schematic diagram illustrating an example of a neural network used in the third embodiment. As illustrated in FIG. 15, as an example, the neural network MD3 is a K layer (K is a natural number) neural network, the input layer has 5N+3 (N is a natural number) neurons, the intermediate layer has 5N neurons, and the output layer has M (M is a natural number) neurons. Each neuron included in the input layer and the intermediate layer is fully connected to a neuron in the next layer, as an example. In addition, the neuron in the intermediate layer performs feedback by weighting the input with its own output.

The neurons L_{1,1} to L_{1,N} of the input layer of the neural network are input with data 1 to N of the eddy current sensor 150-1, . . . , and data 1 to N of the eddy current sensor 150-8 which are signals corresponding to the respective wafer radial positions after preprocessing is performed on the output signals from the eddy current sensors 150-1, . . . , and 150-8 having the same number of times of rotation of the table of S-4 times.

Similarly, data 1 to N of the eddy current sensor 150-1, . . . , and data 1 to N of the eddy current sensor 150-8 which are signals corresponding to the respective wafer radial positions after preprocessing is performed on the output signals from the eddy current sensors 150-1, . . . , and 150-8 having each of the numbers of times of rotation of the table of S-3, S-2, S-1, and S times are input.

In addition, thickness data on the polishing pad 111 (pad thickness data), rotation speed data on the polishing table 110 (table rotation speed data), and rotation speed data on the polishing head 120 (carrier rotation speed data) are respectively input to the neurons L_{1,5N+1} to L_{1,U×5+3} in the input layer of the neural network. The respective metal line heights at the radii r₁ to r_{M} are output from the output layer of the neural network.

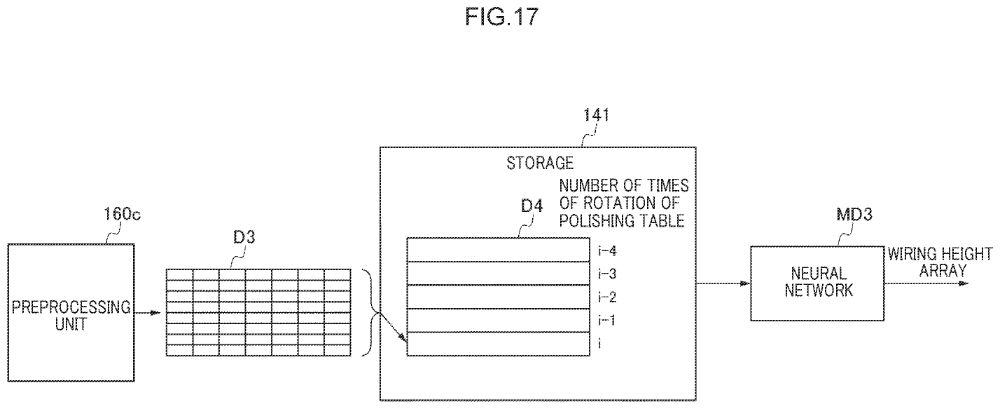

FIG. 17 is a schematic diagram illustrating an example of a flow of data at the time of inference of the neural network used in the third embodiment. As illustrated in FIG. 17, during the polishing processing, every time the polishing table makes one rotation (or every time each of the eddy current sensors 150-1 to 150-8 passes under the substrate 121), the preprocessing unit 160c executes preprocessing on the output signals of the eddy current sensors 150-1 to 150-8. Thus, the preprocessed data D3 is output from the preprocessing unit 160c, and the preprocessed data D3 is stored in the storage 141.

Then, every time the polishing table makes five rotations, the prediction unit 164c reads the latest five pieces of preprocessed data of i-4 to i (i is an integer of 5 or more), in the number of times of rotation of the polishing table, from the storage 141, and the read five pieces of preprocessed data D4 are input to the learned neural network MD3. Thus, the array height array is output from the learned neural network MD3.

As described above, in the third embodiment, the input of the machine learning model (here, the neural network MD3) is data after the preprocessing is executed on the output signal at each position facing the target substrate, in the plurality of cycles of polishing-table rotation of the plurality of eddy current sensors.

Thus, by using the output signals of the plurality of times of circling, even if the movement loci of the eddy current sensor based on the substrate are different for each time of circling of the specific eddy current sensor, the influence can be offset, so that the estimation accuracy of the metal line height can be improved. By using a plurality of output signals of the eddy current sensors in the same circling, even if noise is placed on one output signal, if no noise is placed on the other output signals, the metal line height can be estimated, so that the robustness of estimation of the metal line height can be improved.

It should be noted that in the third embodiment, the number of eddy current sensors may be 2 to 7 or 9 or more, or one, and has only to be one or more.

It should be noted that in the third embodiment, the input of the machine learning model is the data after the preprocessing is executed on the output signal at each position facing the target substrate in the plurality of cycles of polishing-table rotation of the plurality of eddy current sensors, but the present invention is not limited thereto, and the input of the machine learning model may be the data after the preprocessing is executed on the output signal at each position facing the target substrate in the plurality of cycles of polishing-table rotation of “one” eddy current sensor. Thus, by using the output signals of the plurality of times of circling, even if the movement loci of the eddy current sensor based on the substrate are different for each time of circling of the specific eddy current sensor, the influence can be offset, so that the estimation accuracy of the metal line height can be improved.

It should be noted that the order of the processing of the noise removal filter 161, the data interpolation unit 162, and the offset processing unit 163 is not limited to this order, and is in random order.

It should be noted that in each embodiment, after the learned machine learning model is completed, the processor 142 may cause the learned machine learning model (for example, a neural network) to relearn using the output signal of the eddy current sensor during polishing processing. Thus, even after the polishing apparatus is operated, since relearning is performed using the output signal of the eddy current sensor during polishing processing, the prediction accuracy of the metal line height can be improved.

It should be noted that a part or all of the processing of the processor 142 may be executed by another information processing system or may be executed by an information processing system mounted on a cloud.

Note that at least a part of the controller 140 described in the above-described embodiment may be configured by hardware or software. In the case of a hardware configuration, a program that implements at least some functions of the controller 140 may be stored in a recording medium such as a flexible disk or a CD-ROM, and may be read and executed by a computer. The recording medium is not limited to a removable recording medium such as a magnetic disk or an optical disc, and may be a fixed recording medium such as a hard disk device or a memory.

In addition, a program for realizing at least some functions of the controller 140 may be distributed via a communication line (including wireless communication) such as the Internet. Further, the program may be distributed via a wired line or a wireless line such as the Internet or stored in a recording medium in an encrypted, modulated, or compressed state.

Furthermore, the controller 140 may be caused to function by an information processing system including one or more information processing apparatuses. In the case of using a plurality of information processing apparatuses, one of the information processing apparatuses may be a computer, and the function may be achieved as at least one unit of the controller 140 by the computer executing a predetermined program.

In the invention of the method, all the steps may be achieved by automatic control by a computer. In addition, while each step is caused to be performed by a computer, progress control between the steps may be performed by a human hand. In addition, at least some of all steps may be performed by a human hand.

As described above, the present invention is not limited to the above-described embodiments as they are, and can be embodied by modifying the components within a scope without departing from the gist of the present invention in the implementation stage. In addition, various inventions can be formed by appropriately combining a plurality of components disclosed in the above embodiments. For example, some components may be deleted from all the components shown in the embodiments. Furthermore, components ranging over different embodiments may be appropriately combined.

### REFERENCE SIGNS LIST

100 polishing apparatus
110 polishing table
111 polishing pad
120 polishing head
121 substrate
122 airbag
1221 to 1224 section
130 liquid supply mechanism
140 controller
141 storage
142 processor
143 input/output interface
150 eddy current sensor
160, 160b, 160c preprocessing unit
161 noise removal filter
162 data interpolation unit
163 offset processing unit
164, 164b, 164c prediction unit
165 determination unit
166 pressure control unit

1. A polishing apparatus comprising:
a polishing table provided with an eddy current sensor, the polishing table configured to rotate;
a polishing head configured to face the polishing table, the polishing head configured to rotate, the polishing head having a surface which faces the polishing table and to which a substrate is configured to be attached; and
a processor configured to generate preprocessed data on a target substrate by executing predetermined preprocessing on an output signal when the eddy current sensor is at each position facing a target substrate during polishing processing of a target substrate to determine a metal line height at at least one position of the target substrate by inputting preprocessed data on the target substrate to a learned machine learning model using a learning data set in which data after predetermined preprocessing is executed on an output signal when the eddy current sensor is at each position facing a substrate is set as an input and a metal line height at at least one position of the substrate is set as an output.

2. The polishing apparatus according to claim 1, wherein when the determined metal line height reaches a predetermined metal line height, the processor performs control to finish polishing of the target substrate.

3. The polishing apparatus according to claim 1,
wherein the polishing head is provided with a plurality of airbag for pressing a substrate, and
wherein the processor controls pressure in each the airbag according to distribution of the determined metal line height.

4. The polishing apparatus according to claim 1,
wherein an input of the machine learning model further includes a thickness of a polishing pad, a rotation speed of a polishing table, and/or a rotation speed of a polishing head.

5. The polishing apparatus according to claim 1,
further comprising a plurality of the eddy current sensors, and
wherein an input of the machine learning model is data after the preprocessing is executed on an output signal at each position facing the target substrate in identical polishing-table rotation-circling of the plurality of the eddy current sensors.

6. The polishing apparatus according to claim 1,
further comprising a plurality of the eddy current sensors, and
wherein an input of the machine learning model is data after the preprocessing is executed on an output signal at each position facing the target substrate in a plurality of cycles of polishing-table rotation of the plurality of the eddy current sensors.

7. The polishing apparatus according to claim 1, wherein an input of the machine learning model is data after the preprocessing is executed on an output signal at each position facing the target substrate in a plurality of cycles of polishing-table rotation of the plurality of the one eddy current sensor.

8. The polishing apparatus according to claim 1, wherein the processor causes the learned machine learning model to relearn using an output signal of an eddy current sensor during polishing processing.

9. An information processing system comprising:
a preprocessing unit configured to generate preprocessed data on a target substrate by executing predetermined preprocessing on an output signal when an eddy current sensor is at each position facing a target substrate during polishing processing of a target substrate; and
a prediction unit configured to determine a metal line height at at least one position of the target substrate by inputting preprocessed data on the target substrate to a learned machine learning model using a learning data set in which data after predetermined preprocessing is executed on an output signal when the eddy current sensor is at each position facing a substrate is set as an input and a metal line height at at least one position of the substrate is set as an output.

10. An information processing method comprising:
a preprocessing step of generating preprocessed data on a target substrate by executing predetermined preprocessing on an output signal when an eddy current sensor is at each position facing a target substrate during polishing processing of a target substrate; and
a prediction step of determining a metal line height at at least one position of the target substrate by inputting preprocessed data on the target substrate to a learned machine learning model using a learning data set in which data after predetermined preprocessing is executed on an output signal when the eddy current sensor is at each position facing a substrate is set as an input and a metal line height at at least one position of the substrate is set as an output.

11. A non-transitory computer readable medium storing a program for causing a computer to function as:
a preprocessing unit configured to generate preprocessed data on a target substrate by executing predetermined preprocessing on an output signal when an eddy current sensor is at each position facing a target substrate during polishing processing of a target substrate; and
a prediction unit configured to determine a metal line height at at least one position of the target substrate by inputting preprocessed data on the target substrate to a learned machine learning model using a learning data set in which data after predetermined preprocessing is executed on an output signal when the eddy current sensor is at each position facing a substrate is set as an input and a metal line height at at least one position of the substrate is set as an output.
